(19) United States
(12) Patent Application Publication
(10) Pub. No.: US 2025/0309760 A1
(43) Pub. Date: Oct. 2, 2025

(54) HIGH-DENSITY POWER DELIVERY SYSTEM WITH ORTHOGONAL POWER FLOW

(71) Applicant: Empower Semiconductor, Inc., San Jose, CA (US)

(72) Inventors: Luca Vassalli, San Jose, CA (US); Peter Charles Born, Palm Springs, CA (US)

(73) Assignee: Empower Semiconductor, Inc., San Jose, CA (US)

(21) Appl. No.: 19/098,821

(22) Filed: Apr. 2, 2025

Related U.S. Application Data
(60) Provisional application No. 63/573,250, filed on Apr. 2, 2024.

(51) Int. Cl. H02M 3/00; G06F 1/26; H02M 1/00; H05K 1/02; H05K 1/14

(52) U.S. Cl. CPC H02M 3/003; G06F 1/26; H02M 1/007; H05K 1/0203; H05K 1/141; H05K 2201/049

(57) ABSTRACT

An electronic device includes a power plane arranged to receive input power and to distribute the input power to a plurality of blade board assemblies. Each of the blade board assemblies include one or more DC to DC converter circuits that convert the received power into power that is delivered to a processor. Metallic bus bars are attached to each blade board assembly to conduct high current from the power plane, across the blade board assembly and to the DC to DC converter circuits. After DC to DC conversion by the DC to DC converter circuits, additional bus bars are used to conduct the high current across the blade board assembly to the processor, which may be attached to a motherboard.

### CROSS-REFERENCES TO OTHER APPLICATIONS

This application claims priority to U.S. provisional patent application Ser. No. 63/573,250, for “POWER BRANCH WITH VERTICAL POWER FLOW” filed on Apr. 2, 2024 which is hereby incorporated by reference in entirety for all purposes.

### FIELD

The described embodiments relate generally to solid-state power delivery systems containing one or more semiconductor dies. More particularly, the present embodiments relate to high-density, high-current power delivery systems arranged to transfer power to a processor.

### BACKGROUND

Currently there are a wide variety of electronic devices that include processors or other components that operate at low voltages and high input currents. Direct current (DC) to DC converters can be used to convert input power into a lower voltage output power that is suitable for such processors. The reduction in voltage is associated with an increase in current that results in significant power loss when conducted through traditional circuit boards, etc. New electronic devices need power conversion circuits and architectures that have reduced power loss when conducting high currents.

### SUMMARY

In some embodiments, an electronic device includes a power plane arranged to distribute power. The power plane includes a top surface opposite a bottom surface. The electronic device further includes a first blade assembly including a first blade board having a first front surface opposite a first back surface. The first front surface and first back surface extend between a first top end and a first bottom end. The first blade board is arranged perpendicular to the power plane such that the first top end is proximate the bottom surface of the power plane. A first DC to DC converter circuit is disposed on the first front surface and a second DC to Dc converter circuit is disposed on the first back surface, wherein each of the first and second DC to Dc converter circuits are arranged to receive power from the power plane at a first voltage and to generate power proximate the first bottom end at a second voltage that is lower than the first voltage. Additionally, the electronic device includes a second blade assembly including a second blade board having a second front surface opposite a second back surface. The second front surface and the second back surface extend between a second top end and a second bottom end, the second blade assembly positioned adjacent the first blade assembly such that the first front surface is opposite of and parallel to the second back surface. The second blade board is arranged perpendicular to the power plane such that the second top end is proximate the bottom surface of the power plane. A third DC to DC converter circuit is disposed on the second front surface and a fourth DC to Dc converter circuit is disposed on the second back surface, wherein each of the third and the fourth DC to DC converter circuits are arranged to receive power from the power plane at the first voltage and to generate power proximate the second bottom end at a second voltage that is lower than the first voltage.

In some embodiments, the first blade assembly includes a first power output bus disposed proximate the first bottom end, wherein the second blade assembly includes a second power output bus disposed proximate the second bottom end and wherein the first and the second power output busses are arranged to be electrically coupled to a motherboard positioned perpendicular to each of the first and the second blade boards. In some embodiments, the first power output bus includes a first positive output bus bar attached to the first front surface of the first blade board. Additionally, the first power output bus includes a first negative output bus bar attached to the first back surface of the first blade board. In various embodiments, the first power positive output bus bar and the first negative output bus bar each have a thickness greater than half a thickness of the first blade board.

In some embodiments, the second power output bus includes a second positive output bus bar attached to the second front surface of the second blade board. Additionally, the second power output bus includes a second negative output bus bar attached to the second back surface of the second blade board. In various embodiments, the first blade assembly includes a first positive power input bus bar and a second positive power input bus bar disposed proximate the first top end and arranged to be electrically connected to the power plane to receive power at the first voltage. In some embodiments, the first blade assembly includes a controller circuit arranged to control the first and second DC to DC converter circuits. In various embodiments, the controller circuit is arranged to control the third and fourth DC to DC converter circuits.

In some embodiments, the power plane includes a communication bus coupled to the controller circuit. In various embodiments, the power plane includes a preliminary DC to DC converter circuit arranged to receive power at a third voltage and to generate power at the first voltage, wherein the third voltage is greater than the first voltage. In some embodiments, the power plane includes a preliminary DC to DC converter circuit.

In some embodiments, an electronic system includes a power plane. The power plane includes a top surface opposite a bottom surface. The power plane is arranged to receive power at a power input and to distribute the received power to a first power interconnect and to a second power interconnect. Each of the first and the second power interconnects are disposed on the bottom surface. The electronic system further includes a first blade plane arranged perpendicular to the power plane and electrically coupled to the first power interconnect. The first blade plane includes first and second DC to DC converter circuits each arranged to receiver power via the first power interconnect at a first voltage and to generate first output power at a first output terminal at a second voltage. The first voltage is greater than the second voltage. Additionally, the electronic system includes a second blade plane arranged perpendicular to the power plane and electrically coupled to the second power interconnect. The second blade plane includes third and fourth DC to DC converter circuits each arranged to receive power via the second power interconnect at the first voltage and to generate second output power at a second output terminal at the second voltage.

In some embodiments, each of the first power output terminal and the second power output terminal are arranged to be connected to a motherboard that includes a processor arranged to receive the first output power and the second output power. In various embodiments, the first blade plane includes a first positive input bus bar and first negative input bus bar that are each connected to the first power interconnect. In some embodiments, the first positive power input bus bar is disposed on a first side of the first power plane and wherein the first negative power input bus bar is disposed on a second side of the first power plane, wherein the first side is opposite the second side.

In some embodiments, each of the first positive and the first negative input bus bars are formed from an electrically conductive metal and are attached to the first blade plane via an electrically conductive material. In various embodiments, the first output terminal includes a first positive power output bus bar and a first negative power output bus bar. In some embodiments, the first positive power output bus bar is disposed on a first side of the first power plane and the first negative power output bus bar is disposed on a second side of the first power plane, wherein the first side is opposite the second side. In various embodiments, the power plane includes a power plane DC to DC converter circuit that receives power from the power input at a third voltage and generates the power distributed to the first power interconnect, wherein the third voltage is greater than the first voltage.

In some embodiments, a method involves transferring power via a power plane from a power input to first and second power interconnects disposed on a surface of the power plane. The method further involves converting power received from the first power interconnect via a first blade assembly. The first blade assembly includes first and second DC to DC converters arranged to receive power via the first power interconnect at a first voltage and to generate first output power at a first power output terminal at a second voltage, wherein the first voltage is greater than the second voltage. Additionally, the method involves converting power received from the second power interconnect via a second blade assembly. The second blade assembly includes third and fourth DC to DC converters arranged to receive power via the second power interconnect at the first voltage and to generate second output power at a second output terminal at the second voltage.

To better understand the nature and advantages of the present disclosure, reference should be made to the following description and the accompanying figures. It is to be understood, however, that each of the figures is provided for the purpose of illustration only and is not intended as a definition of the limits of the scope of the present disclosure. Also, as a general rule, and unless it is evident to the contrary from the description, where elements in different figures use identical reference numbers, the elements are generally either identical or at least similar in function or purpose.

### BRIEF DESCRIPTION OF THE DRAWINGS

FIG. 1A is a simplified isometric view of an electronic device that includes orthogonal blade assemblies according to some embodiments of the present disclosure;

FIG. 1B is a simplified isometric view of back surface of a blade assembly that is used in the electronic device shown in FIG. 1A;

FIG. 1C illustrates a simplified cross-sectional view of the electronic device shown in FIG. 1A;

FIG. 1D illustrates a simplified power delivery schematic of the electronic device shown in FIG. 1A;

FIG. 2 illustrates a simplified cross-sectional view of an electronic device with coldplates attached to front and back surfaces of each blade assembly, according to embodiments of the disclosure;

FIG. 3 illustrates a simplified plan view of a vertical blade assembly of an electronic device, according embodiments of the disclosure;

FIG. 4 illustrates a simplified plan view of a back surface of a blade assembly, according to embodiments of the present disclosure;

FIG. 5 illustrates a simplified bottom view of a DC to DC converter module that can be attached to a vertical blade assembly, according to embodiments of the disclosure; and

FIG. 6 illustrates a simplified perspective view of an electronic component including a DC to DC conversion circuit and that can be attached to a power plane of an electronic device, according embodiments of the disclosure.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Certain aspects of the present disclosure relate to an electronic device including a plurality of vertical blade assemblies that can efficiently power high-current, low-voltage electronic circuits. In some embodiments, the electronic device includes a power plane that receives power at a first voltage, converts the first voltage, via one or more DC to DC converters to a second, lower voltage and distributes the second voltage to each of the plurality of orthogonally oriented blade assemblies attached to the power plane. Each blade assembly receives the second voltage from the power plane and includes a plurality of DC to DC converter circuits that function in parallel to convert the second voltage to a third, lower voltage. Each blade assembly is connected to a motherboard that is oriented orthogonally to the blade assemblies. The blade assemblies deliver the third voltage to the motherboard. The DC to DC converters are each controlled by an integrated control circuit and control of the integrated control circuits is performed by one or more supervisor control circuits that are attached to one or more of the blade assemblies.

A processor (that may include one or more individual processors) or an electronic component is attached to an opposite side of the motherboard and receives the power generated by the plurality of blade assemblies. With each reduction in voltage within the power plane and within the blade assemblies a commensurate increase in current is provided. In one example an input voltage to the power plane is 48 volts at 3 amperes, the power plane converts the 48 volts to 3 volts at 50 amperes and the blade assemblies convert the 3 volts to 1 volt at 200 amperes that is delivered to the mother board. To efficiently conduct these high currents, each blade assembly includes one or more bus bars that form electrical interconnects to the power plane and the motherboard, and also function as power distribution busses that distribute power to and from the plurality of DC to DC converters within each blade assembly.

The use of a power plane with orthogonal blade assemblies enables reduced size, reduced parasitic losses and the ability to deliver input power to the processor via a power plane that is separate from the motherboard to which the processor is attached. In some embodiments a “footprint” of the electronic device is approximately 4 millimeters by 19 millimeters which may be approximately the footprint of the processor. In some embodiments a footprint of the electronic device may be equal to a footprint of the processor, while in other embodiments it may be within 20 percent of the size of the footprint of the processor.

Several illustrative embodiments will now be described with respect to the accompanying drawings, which form a part thereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration. Any embodiment or design described herein as “exemplary” or “example” is not necessarily to be construed as preferred or advantageous over other embodiments or designs.

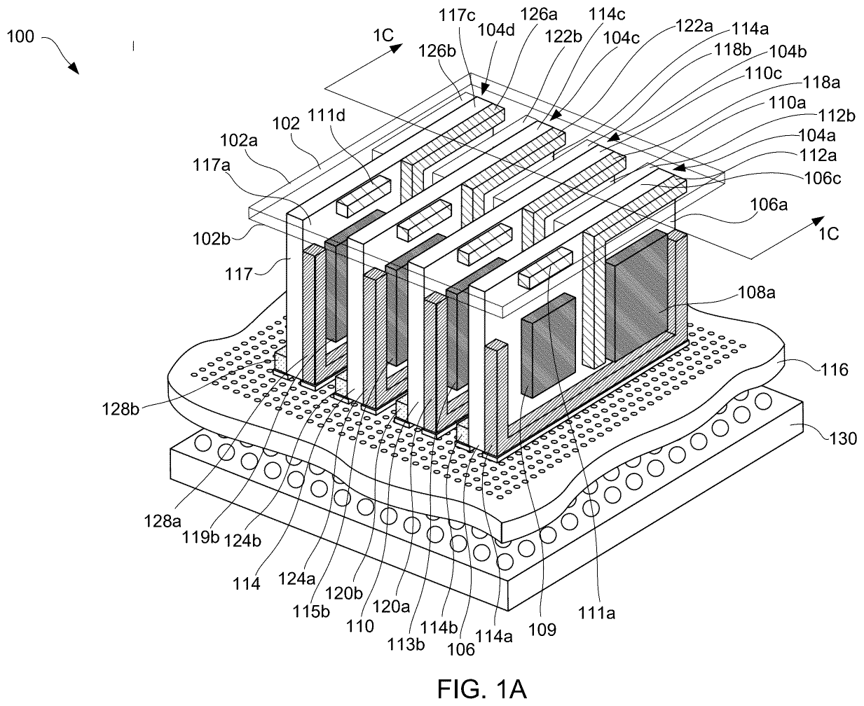

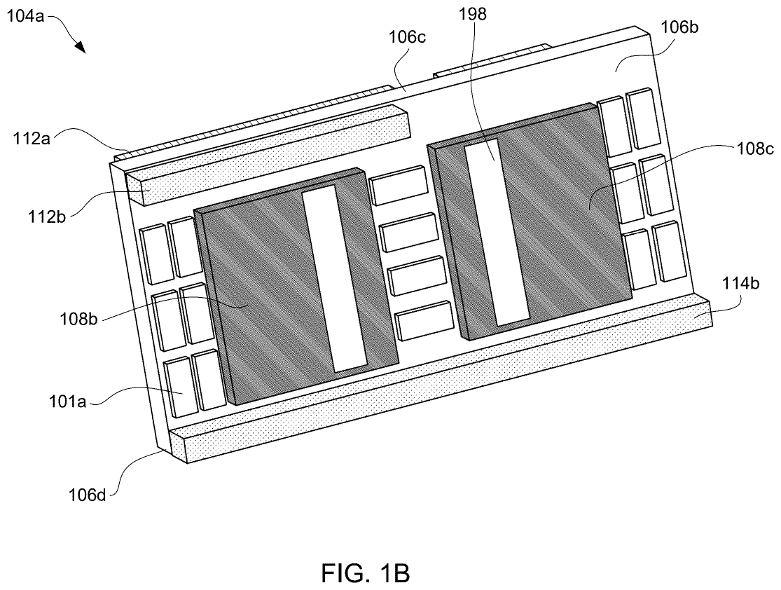

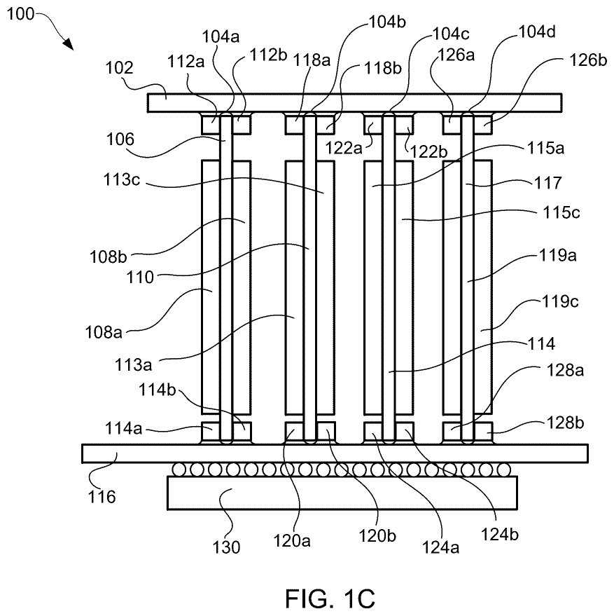

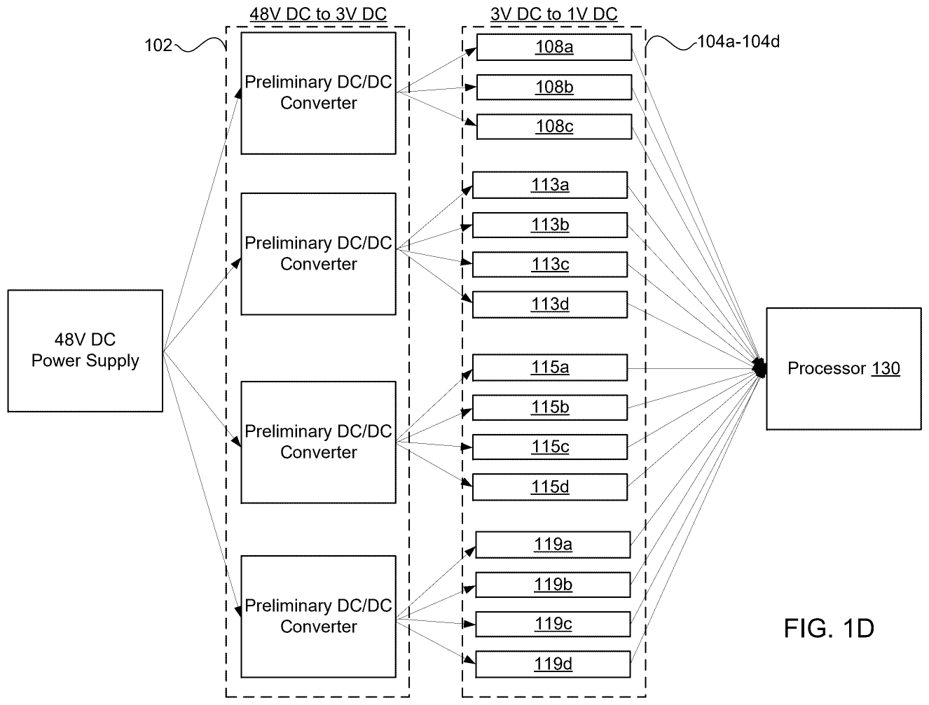

FIG. 1A is a simplified isometric view of an electronic device 100 that includes orthogonal blade assemblies, according to some embodiments of the present disclosure. As shown in FIG. 1A, electronic device 100 can include a power plane 102 (illustrated as semi-transparent) arranged to distribute power wherein the power plane includes a top surface 102a opposite a bottom surface 102b.

The electronic device can further include a first blade assembly 104a including a first blade board 106 (also referred to herein as a blade plane) having a first front surface 106a opposite a first back surface 106b (not shown in FIG. 1A), the first front surface and first back surface extending between a first top end 106c and a first bottom end 106d (not shown in FIG. 1A). Although the terms board, plane and PCB are used herein these terms are not limited to any particular type of electrical routing structure (e.g., printed circuit board) and can include any generally planar structure that conducts electrical signals and may include organic laminate, direct-bonded copper, ceramic/metal combinations, glass, glass hybrids or any other suitable structure. The first blade board 106 is arranged perpendicular to the power plane 102 such that the first top end 106c is proximate the bottom surface 102b of the power plane. A first positive power input bus bar 112a is attached to first front surface 106a and extends parallel to bottom surface 102b of power plane 102. An electrical connection is formed between first positive power input bus bar 112a and power plane 102. A first negative power input bus bar 112b is attached to first back surface 106b (not shown in FIG. 1A) and extends parallel to bottom surface 102b of power plane 102. An electrical connection is formed between first negative power input bus bar 112b and power plane 102.

A first DC to DC converter circuit 108a is disposed on the first front surface 106a along with a local control circuit 109. The local control circuit 109 of the first blade assembly 104a can communicate via communication connector 111a to power plane 102 and/or to other blade assemblies e.g., 104b, 104c, 104d via respective communication connectors. A second DC to DC converter circuit 108b (not shown in FIG. 1A) and a third DC to DC converter circuit 108c (not shown in FIG. 1A) are disposed on the first back surface 106b. Each of the first, second and third DC to DC converter circuits 108a, 108b, 108c, respectively, are arranged to receive power from the power plane 102 via first positive input power bus bar 112a and first negative input power bus bar 112b at a first voltage and to generate power proximate the first bottom end 106d (not shown in FIG. 1A) at a second voltage that is lower than the first voltage. The generated power may be provided at a first positive output power bus bar 114a disposed on first front surface 106a and at a first negative output power bus bar 114b disposed on first back surface 106b. In some embodiments first positive output power bus bar 114a and first negative output power bus bar 114b may extend parallel to power plane 102 and may be arranged to form respective electrical connections to a motherboard 116.

A second blade assembly 104b includes a second blade board 110 having a second front surface 110a opposite a second back surface (not shown in FIG. 1A), the second front surface and second back surface extending between a second top end 110c and a second bottom end (not labeled in FIG. 1A). The second blade assembly 104b is positioned adjacent to the first blade assembly 104a such that the first back surface 106b is opposite of, facing, and parallel to the second front surface 110a. The second blade board 110 is arranged perpendicular to the power plane 102 such that the second top end 110c is proximate the bottom surface 102b of the power plane 102.

A second positive power input bus bar 118a is attached to second front surface 110a and extends parallel to bottom surface 102b of power plane 102. An electrical connection is formed between second positive power input bus bar 118a and power plane 102. A second negative power input bus bar 118b is attached to second back surface and extends parallel to bottom surface 102b of power plane 102. An electrical connection is formed between second negative power input bus bar 118b and power plane 102.

Fourth and fifth DC to DC converter circuits 113a (not shown in FIG. 1A), 113b, respectively, are disposed on the second front surface 110a and sixth (not shown in FIG. 1A) and seventh (not shown in FIG. 1A) DC to DC converter circuits 113c, 113d, respectively, are disposed on the second back surface. Each of the fourth, fifth, sixth and seventh DC to DC converter circuits 113a, 113b, 113c, 113d, respectively, are arranged to receive power from the power plane 102 via second positive input power bus bar 118a and second negative input power bus bar 118b at the first voltage and to generate power proximate the second bottom end at the second voltage that is lower than the first voltage. The generated power may be provided at a second positive output power bus bar 120a disposed on second front surface 110a and at a second negative output power bus bar 120b disposed on second back surface 110b. In some embodiments second positive output power bus bar 120a and second negative output power bus bar 120b may extend parallel to power plane 102 and may be arranged to form respective electrical connections to the motherboard 116.

A third blade assembly 104c includes a third blade board 114 having a third front surface 114a opposite a third back surface (not shown in FIG. 1A), the third front surface and third back surface extending between a third top end 114c and a third bottom end (not labeled in FIG. 1A). The third blade assembly 104c is positioned adjacent to the second blade assembly 104b such that the third front surface 114a is opposite of, facing, and parallel to the second back surface. The third blade board 114 is arranged perpendicular to the power plane 102 such that the third top end 114c is proximate the bottom surface 102b of the power plane 102.

A third positive power input bus bar 122a is attached to third front surface 114a and extends parallel to bottom surface 102b of power plane 102. An electrical connection is formed between third positive power input bus bar 122a and power plane 102. A third negative power input bus bar 122b is attached to third back surface 114b and extends parallel to bottom surface 102b of power plane 102. An electrical connection is formed between third negative power input bus bar 122b and power plane 102.

Eighth and ninth DC to DC converter circuits 115a (not shown in FIG. 1A), 115b, respectively, are disposed on the third front surface 114a and tenth and eleventh DC to DC converter circuits 115c (not shown in FIG. 1A), 115d (not shown in FIG. 1A), respectively, are disposed on the third back surface. Each of the eighth, ninth, tenth and eleventh DC to DC converter circuits 115a, 115b, 115c, 115d, respectively, are arranged to receive power from the power plane 102 via third positive input power bus bar 122a and third negative input power bus bar 122b at the first voltage and to generate power proximate the third bottom end at the second voltage. The generated power may be provided at a third positive output power bus bar 124a disposed on third front surface 114a and at a third negative output power bus bar 124b disposed on third back surface. In some embodiments third positive output power bus bar 124a and third negative output power bus bar 124b may extend parallel to power plane 102 and may be arranged to form respective electrical connections to the motherboard 116.

A fourth blade assembly 104d includes a fourth blade board 117 having a fourth front surface 117a opposite a fourth back surface (not shown in FIG. 1A), the fourth front surface and fourth back surface extending between a fourth top end 117c and a fourth bottom end (not labeled in FIG. 1A. The fourth blade assembly 104d is positioned adjacent to the third blade assembly 104c such that the fourth front surface 117a is opposite of, facing, and parallel to the third back surface. The fourth blade board 117 is arranged perpendicular to the power plane 102 such that the fourth top end 117c is proximate the bottom surface 102b of the power plane 102.

A fourth positive power input bus bar 126a is attached to fourth front surface 117a and extends parallel to bottom surface 102b of power plane 102. An electrical connection is formed between fourth positive power input bus bar 126a and power plane 102. A fourth negative power input bus bar 126b is attached to fourth back surface 106b and extends parallel to bottom surface 102b of power plane 102. An electrical connection is formed between fourth negative power input bus bar 126b and power plane 102.

Twelfth and thirteenth DC to DC converter circuits, 119a (not shown in FIG. 1A), 119b, respectively, are disposed on the fourth front surface 117a and fourteenth and fifteenth DC to DC converter circuits, 119c (not shown in FIG. 1A), 119d (not shown in FIG. 1A), respectively are disposed on the fourth back surface. Each of the twelfth, thirteenth, fourteenth and fifteenth DC to DC converter circuits 119a, 119b, 119c, 119d, respectively, are arranged to receive power from the power plane 102 via fourth positive input power bus bar 126a and fourth negative input power bus bar 126b at the first voltage and to generate power proximate the fourth bottom end at the second voltage. The generated power may be provided at a fourth positive output power bus bar 128a disposed on fourth front surface 117a and at a fourth negative output power bus bar 128b disposed on the fourth back surface. In some embodiments fourth positive output power bus bar 128a and fourth negative output power bus bar 128b may extend parallel to power plane 102 and may be arranged to form respective electrical connections to the motherboard 116.

Each blade assembly 104a-104d is electrically connected to the motherboard 116 and transfers power to the motherboard. One or more processors (or other suitable power consuming device) 130 are attached to an opposite side of the motherboard 116 and use the power generated by each blade assembly 104a-104d. In some embodiments the power plane 102 can receive a first voltage (e.g., 48 volts) and can draw a first current (e.g., 3 amperes). The power plane 102 can include one or more power plane DC to DC conversion circuits that convert the first voltage to a second voltage (e.g., 3 volts) and can deliver a second current e.g., (50 amperes). The power plane can distribute the second voltage to a plurality of blade assemblies (e.g., 104a-104d) that each receive the second voltage and convert the second voltage to a third voltage (e.g., 1 volt) and deliver a third current (e.g., 200 amperes). The sequential reduction in voltage and commensurate increase in current can be arranged to minimize electrical losses, minimize heat dissipation and to maximize the operating efficiency of the system. In particular the bus bars may significantly increase a cross-sectional area of high current conductors in the regions of high currents beyond what is typically achievable with circuit board materials. More particularly, the bus bars can function as electrical connectors, electrical conductors and electrical distribution conduits to significantly increase conductive efficiency at high currents.

In some embodiments, each DC to DC converter may include an integrated control circuit that provides at least partial control over the operation of that particular DC to DC converter circuit.

In one example the integrated control circuit may control a synchronous buck converter using pulse-width modulation based on a predetermined voltage set point. In various embodiments, one or more of the blade assemblies may include a local control circuit (e.g., control circuit 109) that controls of one or more of the integrated control circuits. In some embodiments the local control circuit may provide a predetermined voltage set point to one or more integrated control circuits, for example if the processor is transitioning to a low-power mode or transitioning out of a sleep mode the voltage set points may differ. In various embodiments, the local control circuit may control only the integrated control circuits within that particular blade assembly while in other embodiments the communications bus and connectors may be used to control integrated control circuits in one or more other blade assemblies. The integrated control circuits may provide fast feedback to the local DC to DC converters to, for example, respond to rapid voltage increases or decreases at specific locations on the motherboard. One or more additional control circuits may be disposed on the power plane, and/or on peripheral systems.

As discussed above, one or more of the blade boards may include a communications connector (e.g., connectors 111a, 111d) that enable communications between e.g., a local control circuit (e.g., 108a) and one or more integrated control circuits. The communications connectors may also enable communications between one or more control circuits and an external control circuit for example on a master controller. In some embodiments one or more of the blade assemblies can include a local control circuit (e.g., local control circuit 109) while in other embodiments a local control circuit or other type of control circuit can be attached to other components of the electronic device (e.g. to the motherboard 116, the power plane 102) or can be separate from, yet communicatively coupled to, the electronic device 100. In some embodiments a communications bus that is separate from the power plane 102 may be formed along an edge of the blade assemblies (e.g., a ribbon cable) and may be used to connect to the communications connector and distribute bi-directional communications to each integrated control circuit, a local controller and/or a local supervisor control circuit.

In some embodiments DC to DC conversion circuits (e.g., fourth and fifth DC to DC converter circuits 113a, 113b, respectively) may be formed only on one side of the blade boards and not on opposite sides as described above. In some embodiments more than one DC to DC converter circuit may be formed on a first side of one or more blade boards and more than one DC to DC converter circuit may be formed on a back side. In various embodiment one or more of the blade boards may include two, three, four or more DC to DC converter circuits on a first side and two, three, four or more DC to DC converter circuits on a second side.

As described above, in some embodiments one or more DC to DC converter circuits may be disposed on power plane 102 to convert incoming power for distribution to the blade assemblies and may be described herein as “preliminary DC to DC converter circuits.” In some embodiments a single preliminary DC to DC converter circuit may be used while in other embodiments two, three, four or more preliminary DC to DC converter circuits may be used. In various embodiments one preliminary DC to DC converter circuit per blade assembly is used and the respective preliminary DC to DC converter circuits may be disposed adjacent each power plane (e.g., on a top surface of the power plane over the respective blade assembly) to minimize the high-current conduction losses.

Bus bars (e.g., 112a, 112b, 114a, 114b) may be linear, or may have a linear base with one or more perpendicular extensions that transfer power along both horizontal and vertical dimensions of each blade board. The bus bars not only enable high current conduction with low conduction loss, but they provide improved structural rigidity to the blade boards and to the entire electronic device 100. In some embodiments a DC to DC converter circuit may have a positive input power bus bar that is disposed on two sides (e.g., in an “L” shape) of the DC to DC converter circuit that supplies power to the DC to DC converter circuit and a positive output power bus bar that is disposed on a different two sides (e.g., in an “L” shape) of the DC to DC converter to receive power from the DC to DC converter. In some embodiments negative input and negative output bus bars may have similar geometries, for example in some embodiments they may be linear while in other embodiments they may have a linear base with one or more perpendicular extensions.

The power input bus bars (e.g., 112a, 112b) may form electrical interconnects to the power plane 102. In some embodiments the power input bus bars may be electrically attached to respective locations (e.g., positive and negative metal pads) on the power plane 102 via solder, welding, electrically conductive adhesive or other suitable method. In some embodiments, the power output bus bars (e.g., 114a, 114b) may be electrically attached to respective locations (e.g., positive and negative metal pads) on the motherboard 116 via solder, welding, electrically conductive adhesive or other suitable method. The bus bars may be electrically and mechanically coupled to the respective bus boards via solder, welding, rivets, fasteners, electrically conductive adhesive or other suitable method.

In some embodiments the bus bars are formed from an electrically conductive metal, for example copper, copper-containing alloys, aluminum, steel, titanium or any other suitable metal and may be plated with e.g., nickel, gold, silver, copper or any other suitable metal. In various embodiments the bus bars may have a thickness (from the blade board to a top surface) greater than ¼ thickness of the blade board, greater than ½ thickness of the blade board or greater than ¾ the thickness of the blade board. In some embodiments the bus bars may have a width that is greater than ½ thickness of the blade board or greater than ¾ the thickness of the blade board. In some embodiments a cross-sectional area of the bus bars may not be uniform, for example a base of the bus bars may have a larger cross-sectional area than the perpendicular extensions and visa-versa depending on the needs of the system. In some embodiments one or more of the bus bars may have an I-shape, an L-shape a T-shape, a U shape, a Z-shape, a W-shape or any other suitable geometry.

In some embodiments one or more of the DC to DC converter circuits may be formed on the power plane and/or on the blade boards using chip-on-board technology, system in a package technology, discrete (separately) packaged power (e.g., Field-effect Transistors) and driver devices or any other suitable form. As shown in FIG. 1A, each DC to DC converter is encased in a separate electronic package that may be a flat no-lead, a ball-grid array, a lead-frame or other suitable type of electronic package.

Although four blade assemblies are shown in FIG. 1A, one of skill in the art having the benefit of this application will appreciate that any suitable number of blade assemblies can be used including one, two, three, four, five, six or more. In FIG. 1A the processor 130 is shown as located on an opposite side of the motherboard 116 as the blade assemblies 104a-d, however in other embodiments the processor 130 may be located on the same side of the motherboard 116 as the blade assemblies 104a-d.

In some embodiments one or more heatsinks, cold plates or other suitable cooling device may be utilized to provide cooling to the electronic device 100. For example a heatsink or cold plate may be thermally coupled to one or both sides of each blade assembly 104a-d and/or power plane 102 and may extend beyond a width of each blade assembly 104a-d as described in more detail below.

FIG. 1B is a simplified isometric view of back surface 106b of a blade assembly 104a that can be used in electronic device 100, according to embodiments of the disclosure. As shown in FIG. 1B, blade assembly 104a includes second and third DC to DC converters 108b, 108c, respectively, disposed on the back surface 106b. The first negative power input bus bar 112b is attached to first back surface 106b and extends parallel to bottom surface 102b of power plane 102 (see FIG. 1A). An electrical connection is formed between first negative power input bus bar 112b and power plane 102. The first negative output power bus bar 114b is attached to first back surface 106b. In some embodiments the first negative output power bus bar 114b may extend parallel to power plane 102 (see FIG. 1A) and may be arranged to form respective electrical connections to a motherboard 116. One or more peripheral active and/or passive electrical components (e.g., electrical component 101a) may be attached to first back surface 106b. Although sixteen electrical components are shown on back surface 106b, for simplicity, only electrical component 101a is labeled. In one embodiment peripheral active and/or passive electrical components may include input capacitors, output capacitors, output inductors, trim resistors or other suitable electronic components. In some embodiments one or more of the DC to DC converters may have a thermally conductive insert 198 that may couple thermal energy from one or more internal electronic devices (e.g., field-effect transistor) and may interface with a heatsink or coldplate as discussed in more detail below.

As shown in FIG. 1B, the vertical blade assembly 104a can have a length, and a width. For example, the length of the vertical blade assembly 104a can take on any value from five mm up to 50 mm and greater. Additionally, the width of the vertical blade assembly 104a can take on any value from one mm to 10 mm and greater.

FIG. 1C illustrates a simplified cross-sectional view of the electronic device 100 shown in FIG. 1A. As shown in FIG. 1C, the electronic device 100 includes vertical blade assemblies 104a, 104b, 104c, 104d and each vertical blade assembly includes input power bus bars arranged to receive power from power plane 102 and output power bus bars arranged to form electrical connections to motherboard 116. For example, the vertical blade assembly 104a includes two input power bus bars, positive input power bus bar 112a and negative input power bus bar 112b, each arranged to receive power from the power plane. Additionally, the vertical blade assembly 104a includes two output power bus bars, positive output power bus bar 114a and negative output power bus bar 114b, each arranged to form electrical connections with the motherboard 116 and to provide power to processor 130. Although vertical blade assembly 104a includes two input power bus bars and two output power bus bars, the vertical blade assemblies can include any number of input power bus bars and any number of output power bus bars. For example, any of the vertical blade assemblies can include five input power bus bars while including eight output bus bars.

The processor 130 can receive power from output power bus bars of the blade assemblies via the motherboard 116. As illustrated, the processor 130 can be coupled to a bottom side of the motherboard 116 that is opposite a side of the motherboard 116 that is electrically coupled to the vertical blade assemblies. The processor 130 can be soldered, sintered, welded, or attached via other suitable process to the motherboard 116. For example, the processor 130 can be coupled to the motherboard 116 via a ball-grid array. DC to DC converters of the power blade assemblies can reduce a first voltage received from the power plane 102 to a second, lower voltage and provide the second lower voltage to the motherboard 116.

Blade boards 106, 110, 114, and 117 can be aligned orthogonally with respect to power plane 102 and motherboard 116, meaning that a thickness dimension of each of the blade assemblies 104a, 104b, 104c, 104d can be aligned in a horizontal direction. The blade boards can have six sides: a top, bottom, front, back, left side, and right side. A cross-sectional area of the left and right sides of the blade boards can be larger than cross-sectional areas of the top, bottom, front, and back sides. Gaps or spaces can form between adjacent blade boards. At least a portion of the gaps can be filled with one or more heat sinks or cold plates. For example, in the gap between blade boards 110 and 114, a first heat sink can be attached to DC to DC converter 113c of the blade board 110 and a second heat sink can be attached to DC to DC converter 115a of the blade board 114. Alternatively, a single heat sink can be placed in the gap and attached on one end to DC to DC converter 113c and attached on another end to DC to DC converter 115a. In some embodiments, air or some form of coolant gas or fluid can pass through the gaps separating the base boards.

FIG. 1D illustrates a simplified power delivery schematic of electronic device 100 shown in FIG. 1A. As shown in FIG. 1D, power input to the power plane 102 can be 48 volts at 3 amperes. Preliminary DC to DC converters can convert power at 48 Volts, 3 Amps into power at 3 Volts and 50 Amps. The preliminary DC to DC converters can be components of the power plane 102 or electrically coupled to the power plane 102. While four preliminary DC to DC converters are depicted in FIG. 1D, power delivery to the electronic device 100 can include any number of preliminary DC to DC converters, including a single preliminary DC to DC converter or more than four.

The preliminary DC to DC converters can provide power at 3 Volts to DC to DC converters associated with vertical blade assemblies of the electronic device 100. A first preliminary DC to DC converter can provide power at 3 Volts to DC to DC converters 108a, 108b, and 108c on vertical blade assembly 104a. Vertical blade assembly 104a can accommodate a controller circuit and may have less DC to DC converters than other vertical blade assemblies of the electronic device 100. A second preliminary DC to DC converter can provide power at 3 Volts to DC to DC converters 113a, 113b, 113c, and 113d on vertical blade assembly 104b. Similarly, a third preliminary DC to DC converter can provide power at 3 Volts to DC to DC converters 115a, 115b, 115c, and 115d on vertical blade assembly 104c. A fourth preliminary DC to DC converter can provide power at 3 Volts to DC to DC converters 119a, 119b, 119c, and 119d on vertical blade assembly 104d. While each preliminary DC to DC converter depicted in FIG. 1D is associated with a single vertical blade assembly of the electronic device 100, any number of preliminary DC to DC converters can be associated with the vertical blade assemblies. For example, power delivery to the electronic device can be performed by a number of preliminary DC to DC converters that is greater than, less than, or equal to a number of vertical blade assemblies in the electronic device 100. As appreciated by one of skill in the art the voltages and currents used herein are for example only and any suitable voltages and currents can be used.

The preliminary DC to DC converters or the DC to DC converters in the vertical blade assemblies can be any suitable type of solid-state power converter including but not limited to a synchronous buck converter, a boost converter, a buck-boost converter, a cuk converter, a current source inverter (CSI), multilevel modular converter, etc. The preliminary DC to DC converters or the DC to DC converters of the vertical blade assemblies can use any suitable type or types of semiconductor power devices including but not limited to silicon, silicon-carbide, gallium nitride, diamond, etc.

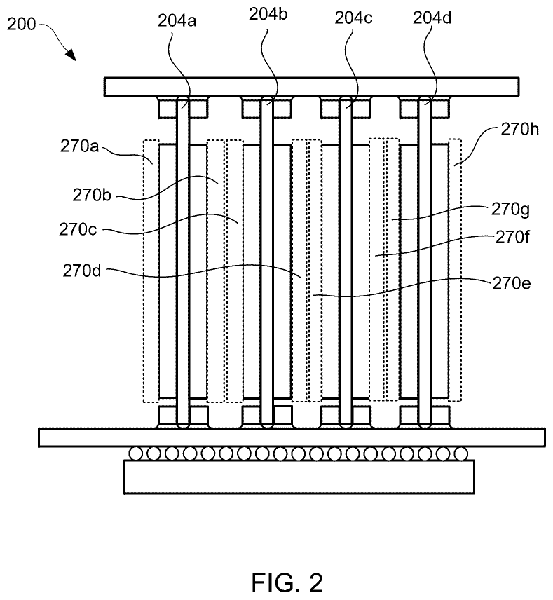

FIG. 2 illustrates a simplified cross-sectional view of an electronic device 200 that may be similar to electronic device 100, shown in FIG. 1A, however in this embodiment coldplates 270a-h have been attached to front and back surfaces of each blade assembly. The electronic device 200 may be or include any of the components, features, or characteristics of any of the electronic devices previously described in the present disclosure. As shown in FIG. 2, coldplates may be thermally coupled to each DC to DC converter circuit and may transfer thermal energy away from each DC to DC converter via solid thermal conduction (e.g., high thermal conductivity materials), via liquid thermal conduction (e.g., a coolant may be passed through the coolant plates, or convection (e.g., air may be passed through cold plates). Alternatively, coldplates 270a-h can be exchanged for heatsinks or any other suitable cooling device.

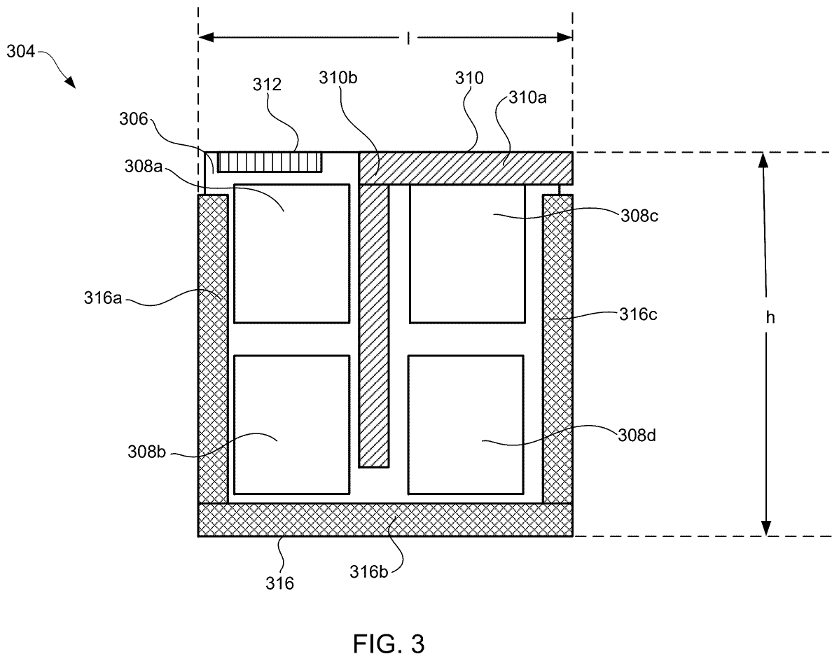

FIG. 3 is a simplified plan view of a vertical blade assembly 304 of an electronic device according to some aspects of the present application. The vertical blade assembly 304 may be or include any of the components, features, or characteristics of any of the vertical blade assemblies previously described. The vertical blade assembly 304 can include components such as a blade board 306, an input bus 310, an input ground bus, controller connectors (e.g., controller connector 312), an output bus 316, an output ground bus, and power components. Examples of the power components can include power component 308a and power component 308b. The power components can also be referred to as leaves. Although four DC to DC converters are shown in FIG. 3, the vertical blade assembly 304 can include any number of DC to DC converters, including a single DC to DC converters, or zero DC to DC converters. For example, the vertical blade assembly 304 can include four additional DC to DC conversion an opposite side (not shown in FIG. 3) for a total of eight DC to DC converters.

The input bus 310 includes a horizontal portion 310a and a vertical portion 310b that together form an L shape. Such a formation allows the input bus 310 to effectively deliver power to each of the four DC to DC converter circuits 308a-d. The vertical portion 310b extends down into a region that separates converter circuits 308a, 308b from converter circuits 308c, 308d. reducing a separation distance between the input bus and the DC to DC converter circuits 308a-d. Similarly, the output bus 316 includes a horizontal portion 316b and two vertical portions 316a and 316c to form a U shape. The vertical portions 316a and 316c reduce a separation between the output bus 316 and the DC to DC converter circuits 308a-d, particularly between the output bus 316 and converter circuits 308a, 308d.

Each bus shown in FIG. 3 can have different voltage ratings, current ratings, or both compared to other busses shown in FIG. 3. For example, the input bus 310 can be rated to withstand relatively high maximum voltages (e.g., at least 50 Volts) and relatively low maximum currents (e.g., at least 3 Amps) compared to the output bus 316, which can be rated to withstand relatively low maximum voltages (e.g., at least 1 Volt) and relatively high maximum currents (e.g., at least 200 Amps). Some of the busses can include multiple segments. For example, the input bus 310 can include two segments 310a, 310b of similar length, a first input segment oriented horizontally and a second input segment oriented vertically. The output bus 316 can include three segments 316a-c, a first output segment oriented horizontally and a second and third output segment oriented vertically. The second and third output segments can have similar lengths and the first output segment can be nearly twice the lengths of the third and second output segments. As shown in FIG. 3, the vertical blade assembly 304 can have a length, l, and a height, h. For example, the length, l, of the vertical blade assembly 304 can take on any value from five mm up to 50 mm. The height, h, of the vertical blade assembly 304 can take on any value from three mm up to 50 mm.

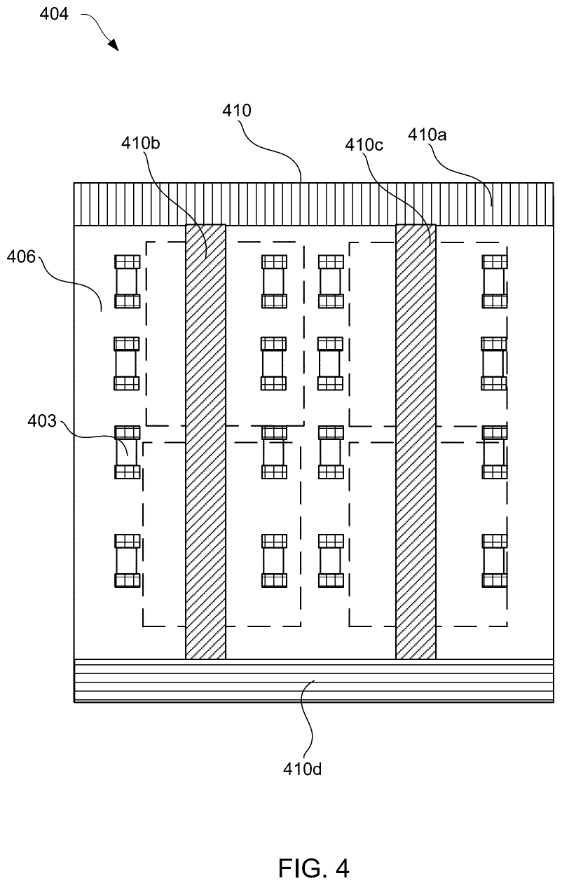

FIG. 4 is simplified plan view of a back surface 406 of a blade assembly 404, according to embodiments of the present disclosure. The vertical blade assembly 404 may be or include any of the components, features, or characteristics of any of the vertical blade assemblies previously described. The vertical blade assembly 404 can include components such as a PCB board 407, a ground bus 416, and additional components. The additional components can be a plurality of capacitors including capacitor 403. Although sixteen capacitors are depicted in FIG. 4, any number of capacitors can be included on the vertical blade assembly 404. Only capacitor 403 is labeled with a reference number for simplicity. The ground bus 410 can include any number of segments. For example, in FIG. 4, the ground bus 410 includes four segments: two horizontally aligned segments 410a, 410d and two vertically aligned segments 410b, 410c. Each of the segments of the ground bus 410 can have similar dimensions or different dimensions in comparison to the other segments of the ground bus.

Top horizontally aligned segment 410a can be electrically coupled to a power plane, (e.g., power plane 102 from FIG. 1a), and bottom horizontally aligned segment 410d can be electrically coupled to a mother board (e.g., mother board 116 from FIG. 1a). The two vertically aligned segments 410b, 410c can form a direct connection between the top horizontally aligned segment 410a and the bottom horizontally aligned segment 410d for efficient current handling. While vertical blade assembly 404 is depicted with four DC to DC converter circuits on a front side, the back surface 406 may include additional DC to DC converter circuits. These additional converter circuits may be connected to positive power planes formed within the vertical blade assembly 404 and/or may use vias to connect to any of the four DC to DC converter circuits on the front side.

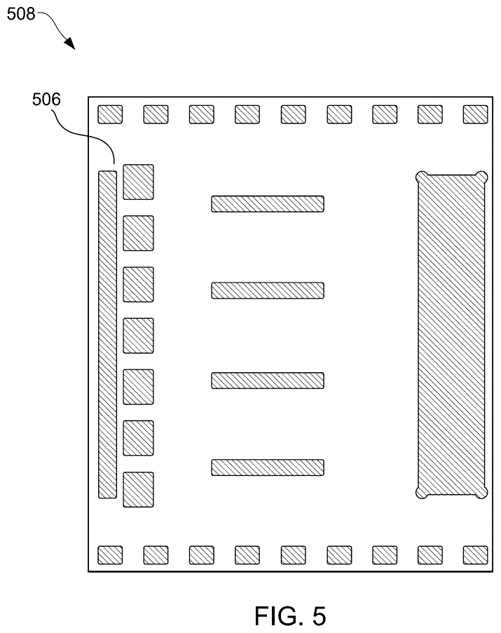

FIG. 5 is a simplified bottom view of a DC to DC converter module 508 that can be used within the vertical blade assemblies, according to some aspects of the present application. The DC to DC converter module 508 may be or include any of the components, features, or characteristics of any of the power components previously described. In some embodiments DC to DC converter modules can be disposed on opposite sides of a blade board such that the connections are mirrored and form a sandwich with connectable links through vias in the blade board. The DC to DC converter module 508 includes a mating surface 506. The mating surface 506 (or portions of the mating surface 506) can be soldered, sintered, welded, or attached via other suitable process to the blade board. The converter module 508 can be a flat no lead (FNL) package that includes a leadframe with an overmolded semiconductor die attached. Additionally, or alternatively, the converter module 508 can include a ball-grid array, or any other type of packaging. Optionally, the converter module 508 can include an organic substrate. The mating surface 506 may include power input connections, power output connections, communication connections for the internal controller, sensing connections to e.g., sense a voltage of the motherboard and other suitable connections.

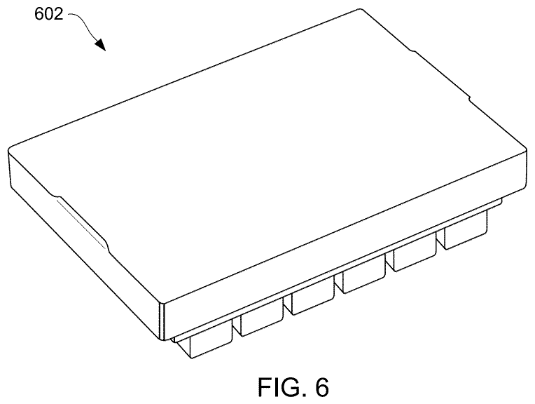

FIG. 6 is a simplified perspective view of an electronic component 602 that can be attached to a power plane (e.g., power plane 102 from FIG. 1A) of an electronic device according to some aspects of the present application. The electronic component 602 can be e.g., attached to a top surface of the power plane via press fit, soldering, copper clip connections, etc. The electronic component 602 can include one or several preliminary DC to DC converters for converting an input power at high voltage, low current, into an output power at lower voltage and higher current. For example, the electronic component can receive input power at 48 Volts and 3 Amps, and provide output power at 3.3 Volts and 50 Amps. In some embodiments only one electronic component 602 can be used on a power plane while in other embodiments two, three, four or more may be used. In one example one electronic component 602 can be attached to a power plane proximate each blade board assembly so it can efficiently supply the blade board assembly with power. The output power of the electronic component 602 can be input power for the blade board assemblies. In some embodiments, the electronic component 602 can replace the power plane and can be attached directly to vertical blade assemblies of the electronic device.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

For simplicity, various internal components, such as the control circuitry, peripheral passives, bus, memory, storage device and other components of electronic device 100 (see FIG. 1A) are not shown in the figures.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In some implementations, operations or processing may involve physical manipulation of physical quantities. Typically, although not necessarily, such quantities may take the form of electrical or magnetic signals capable of being stored, transferred, combined, compared, or otherwise manipulated. It has proven convenient at times, principally for reasons of common usage, to refer to such signals as bits, data, values, elements, symbols, characters, terms, numbers, numerals, or the like. It should be understood, however, that all of these or similar terms are to be associated with appropriate physical quantities and are merely convenient labels. Unless specifically stated otherwise, as apparent from the discussion herein, it is appreciated that throughout this specification discussions utilizing terms such as “processing,” “computing,” “calculating,” “determining,” or the like refer to actions or processes of a specific apparatus, such as a special purpose computer, special purpose computing apparatus or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. An electronic device comprising:
a power plane arranged to distribute power and including a top surface opposite a bottom surface;
a first blade assembly including a first blade board having a first front surface opposite a first back surface, the first front surface and first back surface extending between a first top end and a first bottom end, the first blade board arranged perpendicular to the power plane such that the first top end is proximate the bottom surface of the power plane, a first DC to DC converter circuit disposed on the first front surface and a second DC to DC converter circuit disposed on the first back surface wherein each of the first and the second DC to DC converter circuits are arranged to receive power from the power plane at a first voltage and to generate power proximate the first bottom end at a second voltage that is lower than the first voltage; and
a second blade assembly including a second blade board having a second front surface opposite a second back surface, the second front surface and second back surface extending between a second top end and a second bottom end, the second blade assembly positioned adjacent to the first blade assembly such that the first front surface is opposite of and parallel to the second back surface, the second blade board arranged perpendicular to the power plane such that the second top end is proximate the bottom surface of the power plane, a third DC to DC converter circuit disposed on the second front surface and a fourth DC to DC converter circuit disposed on the second back surface wherein each of the third and the fourth DC to DC converter circuits are arranged to receive power from the power plane at the first voltage and to generate power proximate the second bottom end at a second voltage that is lower than the first voltage.

2. The electronic device of claim 1, wherein the first blade assembly includes a first power output bus disposed proximate the first bottom end, wherein the second blade assembly includes a second power output bus disposed proximate the second bottom end and wherein the first and the second power output busses are arranged to be electrically coupled to a motherboard positioned perpendicular to each of the first and the second blade boards.

3. The electronic device of claim 2, wherein the first power output bus includes a first positive output bus bar attached to the first front surface of the first blade board and includes a first negative output bus bar attached to the first back surface of the first blade board.

4. The electronic device of claim 3, wherein the first power positive output bus bar and the first negative output bus bar each have a thickness greater than half a thickness of the first blade board.

5. The electronic device of claim 2, wherein the second power output bus includes a second positive output bus bar attached to the second front surface of the second blade board and includes a second negative output bus bar attached to the second back surface of the second blade board.

6. The electronic device of claim 1, wherein the first blade assembly includes a first positive power input bus bar and a second positive power input bus bar disposed proximate the first top end and arranged to be electrically connected to the power plane to receive the power at the first voltage.

7. The electronic device of claim 1, wherein the first blade assembly includes a controller circuit arranged to control the first and second DC to DC converter circuits.

8. The electronic device of claim 7, wherein the controller circuit is arranged to control the third and fourth DC to DC converter circuits.

9. The electronic device of claim 7, wherein the power plane includes a communication bus coupled to the controller circuit.

10. The electronic device of claim 1, wherein the power plane includes a preliminary DC to DC converter circuit arranged to receive power at a third voltage and to generate power at the first voltage, wherein the third voltage is greater than the first voltage.

11. The electronic device of claim 1, wherein the power plane includes a preliminary DC to DC converter circuit

12. An electronic system comprising:
a power plane including a top surface opposite a bottom surface, the power plane arranged to receive power at a power input and to distribute the received power to a first power interconnect and to a second power interconnect, each of the first and the second power interconnects disposed on the bottom surface;
a first blade plane arranged perpendicular to the power plane and electrically coupled to the first power interconnect, the first blade plane including first and second DC to DC converter circuits each arranged to receive power via the first power interconnect at a first voltage and to generate first output power at a first output terminal at a second voltage, wherein the first voltage is greater than the second voltage; and
a second blade plane arranged perpendicular to the power plane and electrically coupled to the second power interconnect, the second blade plane including third and fourth DC to DC converter circuits each arranged to receive power via the second power interconnect at the first voltage and to generate second output power at a second output terminal at the second voltage.

13. The electronic system of claim 12, wherein each of the first power output terminal and the second power output terminal are arranged to be connected to a motherboard that includes a processor arranged to receive the first output power and the second output power.

14. The electronic device of claim 12, wherein the first blade plane includes a first positive input bus bar and a first negative input bus bar that are each connected to the first power interconnect.

15. The electronic device of claim 14, wherein the first positive power input bus bar is disposed on a first side of the first power plane and wherein the first negative power input bus bar is disposed on a second side of the first power plane, wherein the first side is opposite the second side.

16. The electronic device of claim 14 wherein each of the first positive input bus bar and the first negative input bus bars are formed from an electrically conductive metal and are attached to the first blade plane via an electrically conductive material.

17. The electronic device of claim 12, wherein the first output terminal includes a first positive power output bus bar and a first negative power output bus bar.

18. The electronic device of claim 17, wherein the first positive power output bus bar is disposed on a first side of the first power plane and wherein the first negative power output bus bar is disposed on a second side of the first power plane, wherein the first side is opposite the second side.

19. The electronic device of claim 12, wherein the power plane includes a power plane DC to DC converter circuit that receives power from the power input at a third voltage and generates the power distributed to the first power interconnect, wherein the third voltage is greater than the first voltage.

20. A method comprising:
transferring power via a power plane from a power input to first and second power interconnects disposed on a surface of the power plane;
converting power received from the first power interconnect via a first blade assembly, the first blade assembly including first and second DC to DC converters arranged to receive power via the first power interconnect at a first voltage and to generate first output power at a first power output terminal at a second voltage, wherein the first voltage is greater than the second voltage; and
converting power received from the second power interconnect via a second blade assembly, the second blade assembly including third and fourth DC to DC converters arranged to receive power via the second power interconnect at the first voltage and to generate second output power at a second power output terminal at the second voltage.
